(19) United States
(12) Patent Application Publication
(10) Pub. No.: US 2026/0188397 A1
(43) Pub. Date: Jul. 2, 2026

(54) INNER AND BOUNDARY WORD LINE READ OFFSETS

(71) Applicant: Micron Technology, Inc., Boise, ID (US)

(72) Inventors: Christina Papagianni, San Jose, CA (US); Murong Lang, San Jose, CA (US)

(21) Appl. No.: 19/003,474

(22) Filed: Dec. 27, 2024

(51) Int. Cl. G11C 16/34; G11C 11/56; G11C 16/04; G11C 16/26

(52) U.S. Cl. CPC G11C 16/3427; G11C 11/5642; G11C 11/5671; G11C 16/0483; G11C 16/26; G11C 16/3495

(57) ABSTRACT

A system and method are provided for reading data from a memory device. The system and method generate a request to read a portion of a memory device and, in response to determining that the portion corresponds to a partially programmed block (PB), determining a condition associated with an individual WL corresponding to the portion of the memory device. The system and method obtain a read level offset from an individual WL offset table, based on the condition associated with the individual WL, and read data from the individual WL using the read level offset obtained from the individual WL offset table.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data in the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 is a block diagram of example inner and boundary word line (WL) read level offset tables, in accordance with some examples.

FIG. 3 is a block diagram of an example of applying an adjusted boundary WL read level offset to read data from a WL, in accordance with some examples.

FIG. 4 is a block diagram of an example table that associates different conditions with different sets of read threshold voltages, in accordance with some examples.

FIG. 5 illustrates a diagram of operations performed using the media operations manager, in accordance with some examples.

FIG. 6 is a block diagram of an example computer system, in accordance with some examples.

### DETAILED DESCRIPTION

The present disclosure configures a system component, such as a memory sub-system controller and/or local media controllers to perform selection of read level offsets used to read data from inner and boundary word lines (WLs) based on various conditions when reading data from a memory device. Specifically, when reading a portion of the memory device that corresponds to a partially programmed block (PB), the component determines a condition associated with an individual WL and obtains a read level offset from an individual WL offset table based on that condition. The component can determine conditions such as slow charge loss (SCL), program erase count (PEC) indicating beginning of life (BOL), middle of life (MOL), or end of life (EOL), and temperature ranges to select appropriate read level offsets. For inner WLs, the component reads data using a first read level offset retrieved from an inner WL offset table. For boundary WLs containing the last programmed page, the component combines the inner WL offset with a modified boundary WL offset to generate a second read level offset. This selection of read level offsets based on various memory conditions helps reduce raw bit error rates (RBER) and improves the overall efficiency and performance of the memory sub-system.

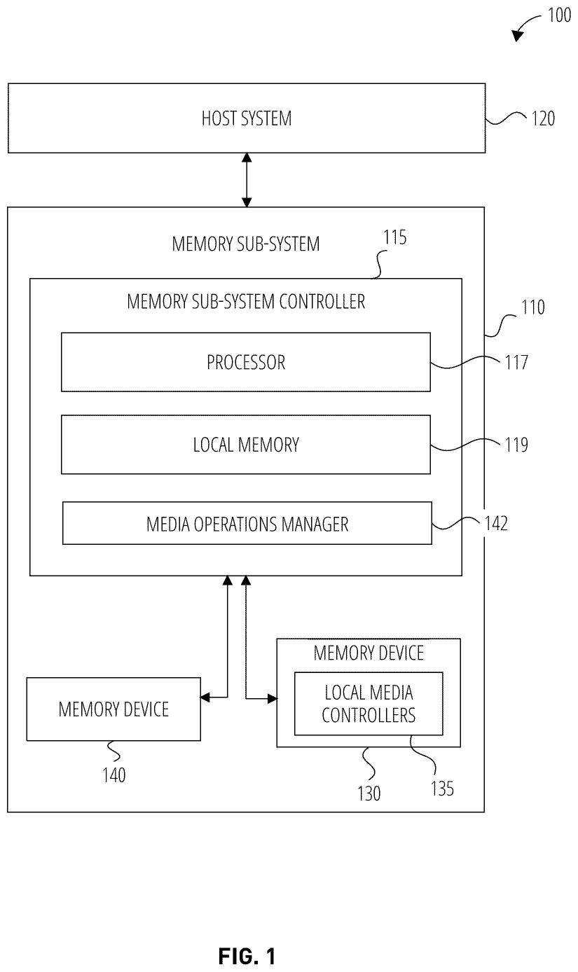

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory devices combined with a local embedded controller for memory management within the same memory device package.

There are challenges in efficiently managing or performing media management operations on typical memory devices. Specifically, certain memory devices, such as NAND flash devices, store data in different WLs. The memory devices can program data into different blocks. Memory blocks that are fully programmed and are closed are referred to as full blocks (FBs). Memory blocks that are not fully programmed (e.g., are still open and have one or more sub-blocks that remain empty and ready to be programmed) are referred to as PBs. In order to reduce read disturb errors and other extrinsic defect related errors when reading data, the controllers can apply offsets to the read threshold voltages used to read data from FBs and PBs. Specifically, when reading data from PBs, the controllers can either apply inner WL offsets or boundary WL offsets, depending on whether the WL being read includes a last programmed page or not.

In some cases, the controllers keep track of which regions of the memory components were last programmed. Namely, the controllers can store an indicator of the location of the last page that was programmed to the set of memory components. The WL that includes the last page that was programmed can be referred to as a boundary WL. All other WLs that do not include the last page can be referred to as inner WLs.

Conventional memory sub-systems use static read level offsets stored in inner and boundary WL offset tables when reading data from PBs. While this approach works adequately for certain memory sub-systems, similar approaches may not work for all generations of memory devices. Specifically, in current tri-level cell (TLC) devices, there may be a significant program erase count (PEC) dependence that is not present in other memory devices. Particularly, at high PEC values (e.g., around 10K cycles) which represent end-of-life (EOL) specifications, the static offset tables may provide read level offsets that are not optimal which can raise the RBER. Such static offset tables are usually optimized for beginning-of-life (BOL) operation, but become inadequate at EOL, resulting in increased RBER that approach or exceed hard decode limits. This issue is expected to become even more pronounced as the number of decks and WLs increase while read/write/block margins decrease. As such, the current static offset approach fails to maintain optimal performance throughout the memory device lifetime. This increased RBER at EOL conditions can trigger excessive error correction operations and impact system performance, particularly after extended periods of charge loss at elevated temperatures.

The present disclosure addresses these technical challenges by providing a memory sub-system controller (memory controller) that can determine specific conditions of the memory device and select appropriate read level voltage offsets accordingly. Specifically, when reading a portion that corresponds to a PB, the memory controller can determine conditions such as slow charge loss (SCL), PEC indicating beginning of life (BOL), middle of life (MOL), or end of life (EOL), and/or temperature ranges. Based on these conditions, the memory controller can select appropriate read level offsets from offset tables-using the inner WL offset table for inner WLs and applying a modified boundary WL offset combined with the inner WL offset for boundary WLs. Rather than using static offsets that become inadequate at different life stages, the memory controller dynamically selects read level offset adjustments based on the current operating conditions.

For example, when PEC indicates EOL conditions where conventional static offsets would result in elevated RBER, the memory controller can select larger offset adjustments to maintain optimal read performance for both the boundary and inner WLs. Similarly, the controller can adjust offsets based on measured SCL and temperature conditions to ensure reliable reads across different operating scenarios. This condition-based adjustment approach helps reduce RBER even in cases where the boundary WL identification may be delayed or incorrect due to programming latency. By intelligently modifying and/or selecting the set of read threshold voltages for both the inner WLs and the boundary WLs based on actual memory device conditions rather than using static values, the system maintains optimal performance throughout the memory device lifetime while improving overall efficiency and reducing error correction operations.

In some examples, a system including a memory device and a processing device, operatively coupled to the memory device, are provided. The processing device can be configured to perform operations, including generating a request to read a portion of the memory device, in response to determining that the portion corresponds to a partially programmed block (PB). The processing device can determine a condition associated with an individual WL corresponding to the portion of the memory device and obtaining a read level offset from an individual WL offset table, based on the condition associated with the individual WL. The processing device can read data from the individual WL using the read level offset obtained from the individual WL offset table.

The portion can include a plurality of WLs where the plurality of WLs includes one or more inner WLs, including the individual WL and a boundary WL. The individual WL offset table can include an inner WL offset table. The processing device can obtain an additional read level offset from a boundary WL offset table based on the condition. In some cases, the processing device can store the inner WL offset table including a first plurality of read level offsets, each associated with a different condition of a plurality of conditions. The processing device can store the boundary WL offset table including a second plurality of read level offsets each associated with the different condition of the plurality of conditions. The boundary WL offset table can represent a set of read level offsets for reading data from one or more WLs of the PB including a last programmed set of data.

In some examples, the processing device reads a first set of data from the one or more inner WLs of the portion using a first read level offset retrieved from the inner WL offset table. The processing device can read a second set of data from the boundary WL of the portion using a combined read level offset, generated based on the first read level offset, and a second read level offset retrieved from the boundary WL offset table. The processing device can add the first read level offset and the second read level offset to generate the combined read level offset.

The processing device can retrieve a read threshold voltage for reading data from the portion and modify the read threshold voltage by the first read level offset to read the first set of data. The processing device can modify the read threshold voltage by the combined read level offset to read the second set of data. The inner WL offset table can associate a first WL group (WLG) with a first set of read level offsets corresponding to different levels of TLC storage, and the inner WL offset table can associate a second WLG with a second set of read level offsets corresponding to the different levels of the TLC storage. The boundary WL offset table can associate the first WLG with a third set of read level offsets, corresponding to the different levels of the TLC storage; the boundary WL offset table associates the second WLG with a fourth set of read level offsets corresponding to the different levels of the TLC storage.

The processing device can maintain a buffer that identifies which region of the memory device has been programmed last and can determine that the portion includes the region of the memory device that has been programmed last. In such cases, the processing device can determine that the portion corresponds to the PB in response to determining that the portion includes the region of the memory device that has been programmed last. The condition can include a PEC; in such cases, the processing device can determine that the PEC associated with the memory device corresponds to a BOL period. The processing device, in response to determining that the PEC corresponds to the BOL period, selects a first set of read level offsets for reading data from inner and boundary WLs of the PB, the first set of read level offsets being associated with a BOL condition.

In some cases, the processing device can determine that the PEC associated with the memory device corresponds to a MOL period. In such cases, the processing device, in response to determining that the PEC associated with the memory device corresponds to the MOL period, selects a second set of read level offsets for reading data from the inner and boundary WLs of the PB, the second set of read level offsets being associated with a MOL condition. The processing device can determine that the PEC associated with the memory device corresponds to an EOL period. In such cases, the processing device, in response to determining that the PEC associated with the memory device corresponds to the EOL period, selects a third set of read level offsets for reading data from the inner and boundary WLs of the PB, the third set of read level offsets being associated with an EOL condition.

In some examples, the condition includes an SCL condition. In such cases, the processing device, can measure SCL associated with the portion of the memory device and, in response to determining that the SCL associated with the portion of the memory device fails to transgress a threshold value, select a first set of read level offsets for reading data from inner and boundary WLs of the PB, the first set of read level offsets being associated with a first SCL condition. The condition can include a temperature condition. In such cases, the processing device can measure temperature associated with the memory device and select a first set of read level offsets for reading data from inner and boundary WLs of the PB based on the measured temperature. The memory device can include a three-dimensional (3D) NAND device.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

In some examples, the memory device 130, including one or more portions (e.g., one or more WLs, one or more WLGs, one or more blocks, one or more memory dies, and/or one or more pages) or group of memory components, including the memory device 130, can be associated with a first reliability (capability) grade, value, measure, or lifetime PEC. The terms “reliability grade,” “value” and “measure” are used interchangeably throughout and can have the same meaning. The memory device 140 (e.g., one or more WLs, one or more WLGs, one or more blocks, one or more memory dies, and/or one or more pages) or group of memory components, including the memory device 140, can be associated with a second reliability (capability) grade, value, measure, or lifetime PEC. In some examples, each memory component (memory device 130 and memory device 140) can store respective configuration data that specifies the respective reliability grade and lifetime PEC, and current PEC and/or other conditions discussed below. In some examples, a memory or register can be associated with all of the memory components (memory device 130 and memory device 140) and can store a table that maps different groups, portions, bins or sets of the memory device 130 and memory device 140 to respective reliability grades, conditions, lifetime PEC values, and/or current PEC values.

In some examples, a memory or register can be associated with all of the memory components (memory device 130 and memory device 140) and can store a table or map that maps different WL, WLGs, SBs, memory dies, and/or portions of the memory components to reliability values that transgress a threshold and/or conditions. Namely, the memory or register can store a map that lists each WL, WLG, and/or SB that has been determined during manufacturing to be defective (e.g., have a reliability value that fails to transgress a reliability threshold). In some cases, the table or map can be generated based on a distribution of errors or defects associated with a certain wafer, die sort, lot, or batch. A determination can be made that the memory sub-system 110 is part of a particular wafer, die sort, lot or batch and can then be loaded with the configuration data that includes the table or map associated with another memory sub-system 110 that is part of the same wafer, die sort, lot, or batch. In some cases, the list of portions that are in the table are referred to as mandatory WLs or mandatory portions (e.g., predetermined portions of the set of memory components). These mandatory portions can be included in an extrinsic defect scan operation (e.g., a read disturb scan operation) to condition performing refresh operations if the RBER of the data read from the portions transgresses a maximum or predefined RBER threshold.

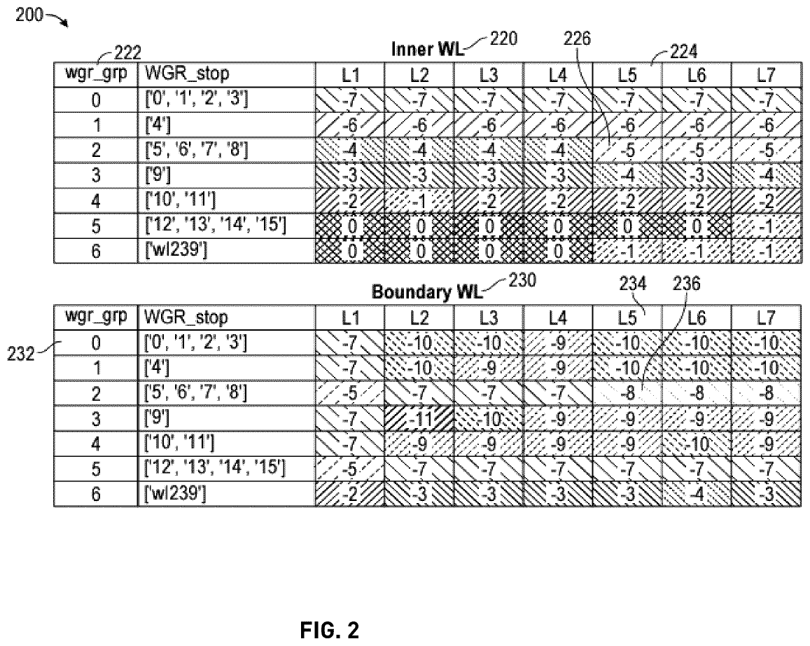

In some cases, the memory or register (e.g., included as part of the local memory 119) can store an inner WL offset table and a boundary WL offset table. In some cases, the inner WL offset table, and the boundary WL offset table can be combined into a single table. For example, as shown in diagram 200 of FIG. 2, the inner WL offset table 220 can store various read level offsets that can be applied to a read threshold voltage when reading one or more inner WLs. Namely, a first WL or WLG 222 can be associated with a first set of read level offsets 224. Each read level offset in the first set of read level offsets 224 can represent a different amount of offsets to apply to the read threshold voltage when reading different levels of TLC storage. Namely, when reading level 1 from the TLC storage in a first WLG (e.g., word line group 4), a −2 DAC offset can be applied; when reading level 2 from the TLC storage in the first WLG, a −1 DAC offset can be applied; and when reading levels 3-7 from the TLC storage in the first WLG, a −2 DAC offset can be applied.

A second WL or WLG 222 can be associated with a second set of read level offsets 224. Each read level offset in the second set of read level offsets 224 can represent a different amount of offsets to apply to the read threshold voltage when reading different levels of TLC storage. Namely, when reading levels 1-4 from the TLC storage in the second WLG (e.g., word line group 6), and when reading levels 5-7 from the TLC storage in the second WLG, a −1 DAC offset can be applied.

The boundary WL offset table 230 can store various read level offsets that can be applied to a read threshold voltage when reading one or more boundary WLs (e.g., WLs that include a last programmed portion or page). Namely, the first WL or WLG 232 can be associated with a second set of read level offsets 234. Each read level offset in the third set of read level offsets 234 can represent a different amount of offsets to apply to the read threshold voltage when reading different levels of TLC storage. These offsets can be the same or different from those mentioned with respect to the inner WL offset table 220. For example, the read level offset 226 in the inner WL offset table 220 for a particular WL and for a particular level of the TLC storage can be a first value of −5 DAC. The read level offset 236 in the boundary WL offset table 230 for the same particular WL, and for the same particular level of the TLC storage, can be a second value of −8 DAC.

In some cases, the media operations manager 142 of FIG. 1 determines that the request to read the portion of the set of memory components corresponds to a PB. In such cases, the media operations manager 142 can access a buffer or storage to identify which WL is indicated to store the last programmed portion or page. The media operations manager 142 can determine a level of the TLC storage that is being read and retrieves the read level offset stored in the inner WL offset table 220. The media operations manager 142 obtains a read threshold voltage for reading data from the portion and modifies the read threshold voltage by the read level offset retrieved from the inner WL offset table 220. The media operations manager 142 can then read each inner WL of the PB using the same modified read threshold voltage. Namely, the media operations manager 142 can read each WL of the PB excluding the identified WL that includes the last programmed portion or page using the read threshold voltage that has been modified by the corresponding value in the inner WL offset table 220.

The media operations manager 142 can obtain the read level offset stored in the boundary WL offset table 230 for the read level being read from the identified WL that includes the last programmed portion or page. The media operations manager 142 can combine (e.g., add) the read level offset stored in the boundary WL offset table 230 with the read level offset that was used to read the inner WL to generate a second read level offset. In some cases, a table (a separate table) can be maintained that includes the already combined values so that the media operations manager 142 does not have to combine the read level offset stored in the boundary WL offset table 230 with the read level offset that was used to read the inner WL to generate the second read level offset (e.g., the second read level offset can be precomputed and stored in a table). The media operations manager 142 can then read the identified WL of the PB that includes the last programmed portion or page using the read threshold voltage adjusted by the second read level offset. In some cases, the media operations manager 142 can determine one or more conditions (e.g., program-erase count, temperature, SCL, and so forth) of the memory sub-system 110 of FIG. 1 and/or the set of components of the memory sub-system 110. The media operations manager 142 can select an additional offset (e.g., also referred to as a set of read level offsets) based on one or more conditions. The additional offset can be applied to the read level offset stored in the boundary WL offset table 230 and/or the inner WL offset table 220 prior to combining that value with the read level offset used to read the inner WL. This can, in some cases, reduce the read threshold voltage used to read the inner WL and/or boundary WL which can reduce the RBER.

Referring back to FIG. 1, a memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device, such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express [PCIe] controller, serial advanced technology attachment [SATA] controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells, such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block comprising SLCs can be referred to as an SLC block, a block comprising MLCs can be referred to as an MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

The media operations manager 142 can generate a request to read a portion of a memory device 140 and, in response to determining that the portion corresponds to a PB, determine a condition associated with an individual WL corresponding to the portion of the memory device 140. The media operations manager 142 can obtain a read level offset from an individual WL offset table (e.g., the inner WL offset table and/or the boundary WL offset table) based on the condition associated with the individual WL and read data from the individual WL using the read level offset obtained from the individual WL offset table.

In some examples, the media operations manager 142, when reading a portion of memory device 130 that corresponds to a PB, determines one or more specific conditions and obtains read level offsets from both the inner WL offset table and boundary WL offset table, where each table contains offsets associated with different operating conditions. The inner WL offset table can store a first plurality of read level offsets, each associated with different conditions such as SCL thresholds, PEC life stages (BOL, MOL, EOL), and temperature ranges. Similarly, the boundary WL offset table can store a second plurality of read level offsets associated with these same conditions.

For inner WLs, the media operations manager 142 can retrieve condition-specific offsets from the inner WL offset table. For boundary WLs containing the last programmed page, the media operations manager 142 combines the condition-specific inner WL offset with a modified condition-specific boundary WL offset. The media operations manager 142 can adapt to operating conditions by measuring SCL, PEC values, and/or temperature, can then select appropriate read level offsets from both tables based on the measured conditions. This ensures optimal offset selection throughout the device lifetime for both inner and boundary WLs. When applying offsets, the media operations manager 142 can retrieve condition-matched offsets from both tables, modifies the boundary WL offset by an adjustment factor, then combines it with the inner WL offset. This dynamic selection of condition-specific offsets from both tables helps minimize RBER across different operating scenarios.

Any discussion with respect to the memory device 130 can similarly be applied to the memory device 140. Any function pertaining to the local media controllers 135 can, in some cases, be performed by the device) memory sub-system controller 115.

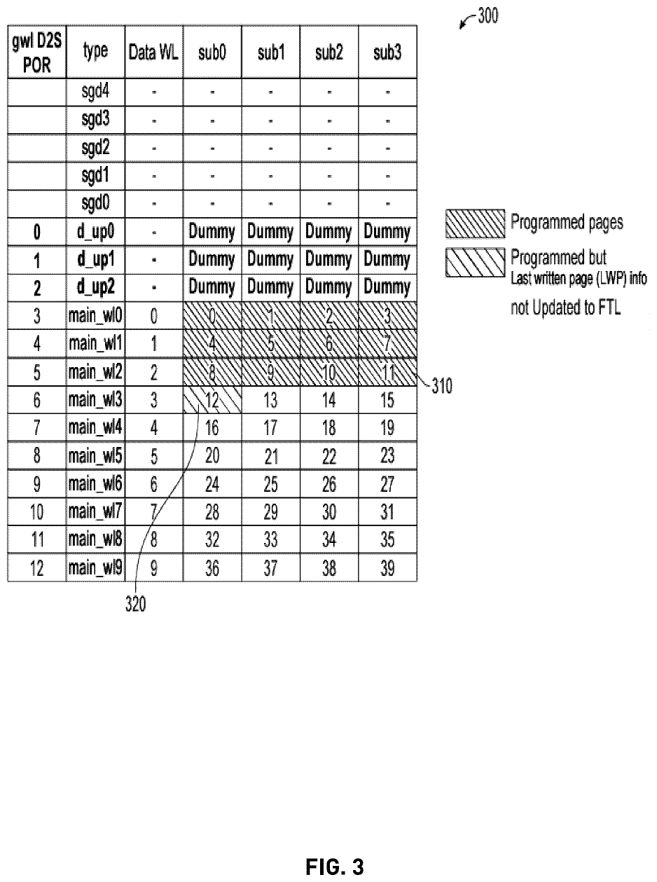

As shown in the diagram 300 of FIG. 3, the media operations manager 142 of FIG. 1 can store or program data sequentially across SBs of the memory device 130 of FIG. 1. The media operations manager 142 can maintain a pointer or buffer that identifies what the last programmed portion or page is in the memory device 130. Specifically, the media operations manager 142 can store a pointer indicating that the SB3 310 in WL5 is the last programmed portion or page. In such cases, when reading data from the WL5, the media operations manager 142 can determine that the WL5 is a PB that includes the last programmed portion or page based on the data stored in the buffer or pointer. The media operations manager 142 can use the read level offset stored in the boundary WL offset table 230 of FIG. 2 together with the read level offset stored in the inner WL offset table 220 of FIG. 2 to read data from the WLG0 (WL5 is in WLG0). In actuality, the pointer or buffer may incorrectly identify the SB3 310 as the last programmed portion because an additional page or portion 320 (e.g., SB0) from the next WL6 may have been programmed before the pointer or buffer was updated to indicate that the portion 320 is the last programmed portion or page. The media operations manager 142 can, in such cases, still consider WL6 to be an empty WL and apply one read level offset to read the data stored in the SB3 310 (e.g., the combined read level offset that includes the offset retrieved from the inner WL offset table 220 and the offset retrieved from the boundary WL offset table 230).

In order to reduce read errors and improve the RBER, the media operations manager 142 can apply an additional offset to reduce (or increase) the read level offset applied to read the data from the boundary WL and/or inner WL. Namely, the media operations manager 142 can dynamically select an additional offset to reduce or increase the read level offset that is used to read data from a WL that is indicated by the pointer or buffer to contain or include the last programmed portion.

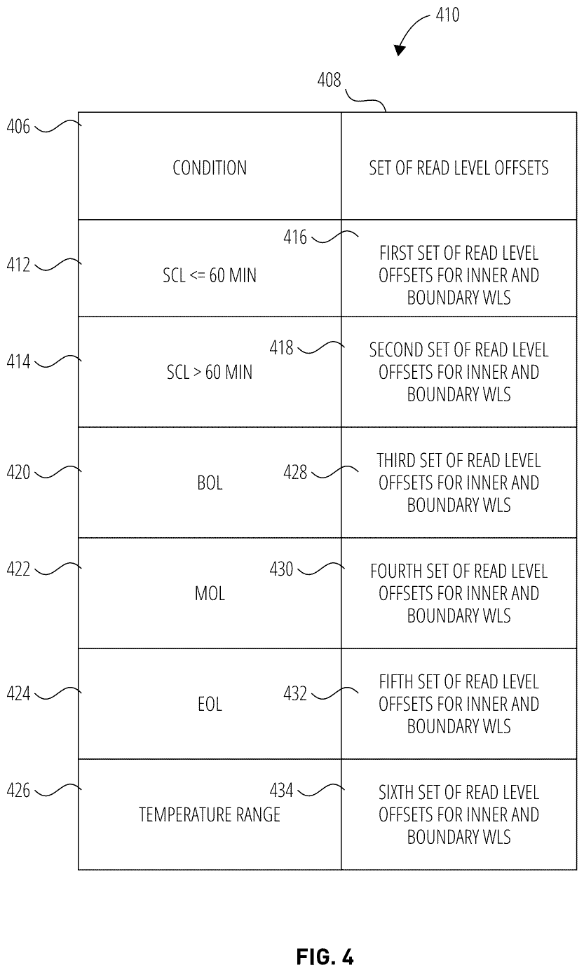

The media operations manager 142 can select a set of read level offsets to reduce (or increase) the read level offset applied to read the data from the boundary WL and/or an inner WL based on various operating conditions of the memory device 130 and/or the memory sub-system 110 of FIG. 1. In some examples, the media operations manager 142 determines a current condition of the memory sub-system 110 and/or the memory devices 130, 140 of FIG. 1. The media operations manager 142 can match the current condition to one of the various conditions in the read level offset table 410 of FIG. 4 to retrieve a corresponding adjustment factor from the set of read level offsets 408 of FIG. 4. The media operations manager 142 can, when applying the read level offset from the boundary WL offset table 230, first modify the read level offset by the retrieved set of read level offsets, such as to reduce the read threshold voltage that would otherwise be used to read the data from the boundary WL. Similarly, the media operations manager 142 can, when applying the read level offset from the inner WL offset table, first modify the read level offset by the retrieved set of read level offsets, such as to reduce the read threshold voltage that would otherwise be used to read the data from the inner WL.

For example, the media operations manager 142 can determine that an individual WL being read corresponds to a PB and is indicated by the buffer or pointer to include the last programmed page. In such cases, the media operations manager 142 can measure an SCL associated with data stored in the individual WL. The media operations manager 142 can determine that the measured SCL is below a threshold to determine that condition 412 of the conditions 406 (of FIG. 4) “SCL<=60 MIN” is met. In such cases, the media operations manager 142 retrieves a first set of read level offsets for inner and boundary WLs associated with the condition 412. The first set of read level offsets 416 of FIG. 4 can include a first read level offset for the inner WLs and a second read level offset for the boundary WL. The media operations manager 142 can then read data from a portion of the PB using the first read level offset when reading inner WLs and using the second read level offset when reading the boundary WL. In some cases, the data can be read from the inner WLs by adjusting the corresponding read threshold voltage stored in the inner WL offset table 220 by the first read level offset obtained from the first set of read level offsets 416. Data can be read from the boundary WLs by adjusting the corresponding read threshold voltage stored in the boundary WL offset table 230 by the second read level offset obtained from the first set of read level offsets 416 combined (e.g., added) to the read threshold voltage used to read data from the inner WL. Namely, the media operations manager 142 can compute a combined read threshold voltage by computing the read threshold voltage used to read the inner WLs with the read level stored in the boundary WL offset table 230 and the second read level offset obtained from the first set of read level offsets 416.

Similarly, in some cases, the media operations manager 142 can determine that the measured SCL is above the threshold to determine that condition 414 of FIG. 4 “SCL>60 MIN” is met. In such cases, the media operations manager 142 retrieves a second set of read level offsets 418 of FIG. 4 for inner and boundary WLs associated with the condition 414. The second set of read level offsets 418 can include a first read level offset for the inner WLs and a second read level offset for the boundary WL. The media operations manager 142 can then read data from a portion of the PB using the first read level offset when reading inner WLs and using the second read level offset when reading the boundary WL. In some cases, the data can be read from the inner WLs by adjusting the corresponding read threshold voltage stored in the inner WL offset table 220 by the first read level offset obtained from the second set of read level offsets 418. Data can be read from the boundary WLs by adjusting the corresponding read threshold voltage stored in the boundary WL offset table 230 by the second read level offset obtained from the second set of read level offsets 418 combined (e.g., added) to the read threshold voltage used to read data from the inner WL. Namely, the media operations manager 142 can compute a combined read threshold voltage by computing the read threshold voltage used to read the inner WLs with the read level stored in the boundary WL offset table 230 and the second read level offset obtained from the second set of read level offsets 418.

In some examples, the media operations manager 142 can compute a PEC value for a portion of the memory devices 130, 140 being read. The media operations manager 142 can determine that the PEC value indicates a beginning of life (BOL) condition 420 of FIG. 4. In such cases, the media operations manager 142 retrieves a third set of read level offsets 428 of FIG. 4 for inner and boundary WLs associated with the BOL condition 420. The third set of read level offsets 428 can include a first read level offset for the inner WLs and a second read level offset for the boundary WL. The media operations manager 142 can then read data from a portion of the PB using the first read level offset when reading inner WLs and using the second read level offset when reading the boundary WL. In some cases, the data can be read from the inner WLs by adjusting the corresponding read threshold voltage stored in the inner WL offset table 220 by the first read level offset obtained from the third set of read level offsets 428. Data can be read from the boundary WLs by adjusting the corresponding read threshold voltage stored in the boundary WL offset table 230 by the second read level offset obtained from the third set of read level offsets 428 combined (e.g., added) to the read threshold voltage used to read data from the inner WL. Namely, the media operations manager 142 can compute a combined read threshold voltage by computing the read threshold voltage used to read the inner WLs with the read level stored in the boundary WL offset table 230 and the second read level offset obtained from the third set of read level offsets 428.

The media operations manager 142 can determine that the PEC value indicates a middle of life (MOL) condition 422 of FIG. 4. In such cases, the media operations manager 142 retrieves a fourth set of read level offsets 430 of FIG. 4 for inner and boundary WLs associated with the MOL condition 422. The fourth set of read level offsets 430 can include a first read level offset for the inner WLs and a second read level offset for the boundary WL. The media operations manager 142 can then read data from a portion of the PB using the first read level offset when reading inner WLs and using the second read level offset when reading the boundary WL. In some cases, the data can be read from the inner WLs by adjusting the corresponding read threshold voltage stored in the inner WL offset table 220 by the first read level offset obtained from the fourth set of read level offsets 430. Data can be read from the boundary WLs by adjusting the corresponding read threshold voltage stored in the boundary WL offset table 230 by the second read level offset obtained from the fourth set of read level offsets 430 combined (e.g., added) to the read threshold voltage used to read data from the inner WL. Namely, the media operations manager 142 can compute a combined read threshold voltage by computing the read threshold voltage used to read the inner WLs with the read level stored in the boundary WL offset table 230 and the second read level offset obtained from the fourth set of read level offsets 430.

The media operations manager 142 can determine that the PEC value indicates an end of life (EOL) condition 424. In such cases, the media operations manager 142 retrieves a fifth set of read level offsets 432 for inner and boundary WLs associated with the EOL condition 424. The first set of read level offsets 416 can include a first read level offset for the inner WLs and a second read level offset for the boundary WL. The media operations manager 142 can then read data from a portion of the PB using the first read level offset when reading inner WLs and using the second read level offset when reading the boundary WL. In some cases, the data can be read from the inner WLs by adjusting the corresponding read threshold voltage stored in the inner WL offset table 220 by the first read level offset obtained from the fifth set of read level offsets 432. Data can be read from the boundary WLs by adjusting the corresponding read threshold voltage stored in the boundary WL offset table 230 by the second read level offset obtained from the fifth set of read level offsets 432 combined (e.g., added) to the read threshold voltage used to read data from the inner WL. Namely, the media operations manager 142 can compute a combined read threshold voltage by computing the read threshold voltage used to read the inner WLs with the read level stored in the boundary WL offset table 230 and the second read level offset obtained from the fifth set of read level offsets 432 of FIG. 4.

In some examples, the media operations manager 142 can compute a temperature value for the memory sub-system 110. The media operations manager 142 can determine that the temperature value falls within a temperature range 426 of FIG. 4. In such cases, the media operations manager 142 retrieves a sixth set of read level offsets 434 of FIG. 4 for inner and boundary WLs associated with the temperature range 426. The sixth set of read level offsets 434 can include a first read level offset for the inner WLs and a second read level offset for the boundary WL. The media operations manager 142 can then read data from a portion of the PB using the first read level offset when reading inner WLs and using the second read level offset when reading the boundary WL. In some cases, the data can be read from the inner WLs by adjusting the corresponding read threshold voltage stored in the inner WL offset table 220 by the first read level offset obtained from the sixth set of read level offsets 434. Data can be read from the boundary WLs by adjusting the corresponding read threshold voltage stored in the boundary WL offset table 230 by the second read level offset obtained from the sixth set of read level offsets 434 combined (e.g., added) to the read threshold voltage used to read data from the inner WL. Namely, the media operations manager 142 can compute a combined read threshold voltage by computing the read threshold voltage used to read the inner WLs with the read level stored in the boundary WL offset table 230 and the second read level offset obtained from the sixth set of read level offsets 434.

The first set of read level offsets 416, second set of read level offsets 418, third set of read level offsets 428, fourth set of read level offsets 430, fifth set of read level offsets 432, and/or the sixth set of read level offsets 434 can be the same or different values.

In some cases, the media operations manager 142 can replace static offset tables with dynamic tables that store condition-specific read level offsets. For example, the media operations manager 142 can stores an inner WL offset table and boundary WL offset table that each contain different sets of read level offsets optimized for BOL and EOL conditions. When reading a PB, the media operations manager 142 determines the current PEC value. If the PEC indicates BOL conditions, the media operations manager 142 retrieves a first set of read level offsets from both tables that are optimized for low PEC values. For inner WLs, the media operations manager 142 applies the BOL-specific inner WL offset directly. For boundary WLs, the media operations manager 142 combines the BOL-specific inner WL offset with the BOL-specific boundary WL offset. Conversely, when PEC indicates EOL conditions (e.g., around 10K cycles), the media operations manager 142 can retrieve and applies larger offset values from both tables that are specifically optimized for high PEC scenarios.

In some examples, the media operations manager 142 can implement a more granular approach by maintaining offset tables with entries for BOL, MOL, and EOL conditions. As the device transitions through different life stages based on PEC values, the media operations manager 142 selects increasingly larger offset values from both tables. For example, at BOL the media operations manager 142 uses smaller offsets since RBER is naturally lower. At MOL, the media operations manager 142 transitions to medium-range offsets. At EOL, where RBER can approach hard decode limits, the media operations manager 142 can select the largest offset values to maintain optimal read performance. This graduated approach ensures the read threshold voltages are properly adjusted throughout the entire device lifetime, rather than using static values that become inadequate as PEC increases.

For device-level conditions, the media operations manager 142 determines the current PEC value across the entire memory device 130 and/or memory sub-system 110. When PEC indicates BOL conditions, the media operations manager 142 retrieves device-wide optimized offsets from both tables. For inner WLs, it applies the BOL-specific inner WL offset directly, while for boundary WLs, the media operations manager 142 combines the BOL-specific inner WL offset with the BOL-specific boundary WL offset. At EOL conditions (e.g., around 10K cycles), the media operations manager 142 retrieves and applies larger offset values optimized for high PEC scenarios.

For WL-specific conditions, the media operations manager 142 can determine conditions associated with individual WLs or WL groups within the memory device 130. The inner WL offset table associates different WL groups with specific sets of read level offsets corresponding to different levels of TLC storage. Similarly, the boundary WL offset table contains offsets optimized for specific WL groups. The media operations manager 142 can also account for localized conditions affecting specific regions of the memory device 130. For example, the media operations manager 142 can measure SCL associated with particular portions of the memory device 130 and select appropriate read level offsets based on whether the measured SCL for those specific portions transgresses defined thresholds. Additionally, the media operations manager 142 can maintain separate offset values for different word line groups (WLGs), allowing for granular optimization based on the physical location and characteristics of specific WLs within the memory device 130. This enables the memory sub-system 110 to account for variations in read performance across different areas of the memory device 130.

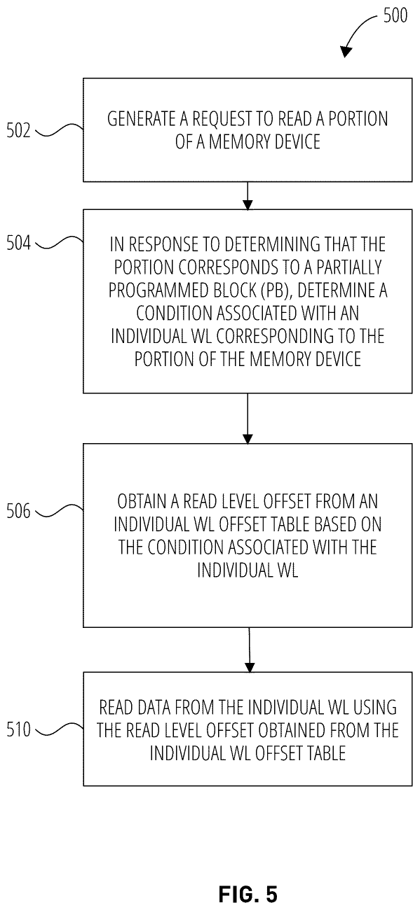

FIG. 5 illustrates a diagram 500 of operations performed using the media operations manager 142 of FIG. 1, in accordance with some examples. The method or process of diagram 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 500 is performed by the memory sub-system controller 115 of FIG. 1, local media controllers 135 of FIG. 1, and/or subcomponents of the memory sub-system controller 115 and/or local media controllers 135. In these examples, the method or process of diagram 500 can be performed, at least in part, by the media operations manager 142 of FIG. 1. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example; other process flows are possible.

Referring now to FIG. 5, the method begins at operation 502 with the media operations manager 142 generating a request to read a portion of a memory device. At operation 504, the media operations manager 142, in response to determining that the portion corresponds to a PB, determines a condition associated with an individual WL corresponding to the portion of the memory device. At operation 506, the media operations manager 142 obtains a read level offset from an individual WL offset table based on the condition associated with the individual WL and, at operation 510, the media operations manager 142 reads data from the individual WL using the read level offset obtained from the individual WL offset table.

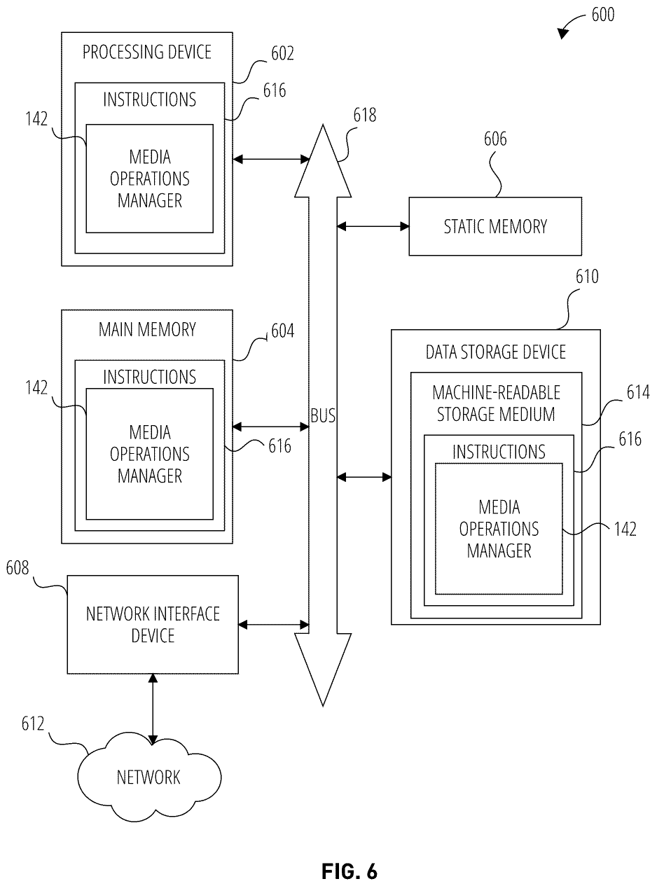

FIG. 6 illustrates an example machine in the form of a computer system 600 within which a set of instructions can be executed for causing the machine to perform any one or more of the methodologies discussed herein. In some examples, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., ROM, flash memory, DRAM such as SDRAM or Rambus DRAM (RDRAM), etc.), a static memory 606 (e.g., flash memory, static random access memory (SRAM), etc.), and a data storage device 610, which communicate with each other via a bus 618.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application-specific integrated circuit (ASIC), a field programmable gate array (FPGA), a digital signal processor (DSP), a network processor, or the like. The processing device 602 is configured to execute instructions 616 for performing the operations and steps discussed herein. The computer system 600 can further include a network interface device 608 to communicate over a network 612.

The data storage device 610 can include a machine-readable storage medium 614 (also known as a computer-readable medium) on which is stored one or more sets of instructions 616 or software embodying any one or more of the methodologies or functions described herein. The instructions 616 can also reside, completely or at least partially, within the main memory 604 and/or within the processing device 602 during execution thereof by the computer system 600, the main memory 604 and the processing device 602 also constituting machine-readable storage media. The machine-readable storage medium 614, data storage device 610, and/or main memory 604 can correspond to the memory sub-system 110 of FIG. 1.

In one example, the instructions 616 include instructions to implement functionality corresponding to providing block failure protection for a zone memory sub-system as described herein. While the machine-readable storage medium 614 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

### Example 1

A system comprising: a memory device; and a processing device, operatively coupled to the memory device, configured to perform operations comprising: generating a request to read a portion of the memory device; in response to determining that the portion corresponds to a partially programmed block (PB), determining a condition associated with an individual WL corresponding to the portion of the memory device; obtaining a read level offset from an individual WL offset table based on the condition associated with the individual WL; and reading data from the individual WL using the read level offset obtained from the individual WL offset table.

### Example 2

The system of Example 1, wherein the portion comprises a plurality of WLs, the plurality of WLs comprising one or more inner WLs including the individual WL and a boundary WL, wherein the individual WL offset table comprises an inner WL offset table, the operations comprising obtaining an additional read level offset from a boundary WL offset table based on the condition.

### Example 3

The system of Example 2, the operations comprising: storing the inner WL offset table comprising a first plurality of read level offsets each associated with a different condition of a plurality of conditions; and storing the boundary WL offset table comprising a second plurality of read level offsets each associated with the different conditions of the plurality of conditions, the boundary WL offset table representing a set of read level offsets for reading data from one or more WLs of the PB comprising a last programmed set of data.

### Example 4

The system of Example 3, the operations comprising: reading a first set of data from the one or more inner WLs of the portion using a first read level offset retrieved from the inner WL offset table; and reading a second set of data from the boundary WL of the portion using a combined read level offset generated based on the first read level offset and a second read level offset retrieved from the boundary WL offset table.

### Example 5

The system of Example 4, the operations comprising: adding the first read level offset and the second read level offset to generate the combined read level offset.

### Example 6

The system of any one of Examples 4-5, the operations comprising: retrieving a read threshold voltage for reading data from the portion; modifying the read threshold voltage by the first read level offset to read the first set of data; and modifying the read threshold voltage by the combined read level offset to read the second set of data.

### Example 7

The system of any one of Examples 3-6, wherein the inner WL offset table associates a first WL group (WLG) with a first set of read level offsets corresponding to different levels of tri-level cell (TLC) storage, wherein the inner WL offset table associates a second WLG with a second set of read level offsets corresponding to the different levels of the TLC storage, wherein the boundary WL offset table associates the first WLG with a third set of read level offsets corresponding to the different levels of the TLC storage, and wherein the boundary WL offset table associates the second WLG with a fourth set of read level offsets corresponding to the different levels of the TLC storage.

### Example 8

The system of any one of Examples 1-7, the operations comprising: maintaining a buffer that identifies which region of the memory device has been programmed last; determining that the portion comprises the region of the memory device that has been programmed last; and determining that the portion corresponds to the PB in response to determining that the portion comprises the region of the memory device that has been programmed last.

### Example 9

The system of any one of Examples 1-8, wherein the condition comprises a program erase count (PEC).

### Example 10

The system of Example 9, the operations comprising: determining that the PEC associated with the memory device corresponds to a beginning of life (BOL) period; and in response to determining that the PEC corresponds to the BOL period, selecting a first set of read level offsets for reading data from inner and boundary WLs of the PB, the first set of read level offsets being associated with a BOL condition.

### Example 11

The system of Example 10, the operations comprising: determining that the PEC associated with the memory device corresponds to a middle of life (MOL) period; and in response to determining that the PEC associated with the memory device corresponds to the MOL period, selecting a second set of read level offsets for reading data from the inner and boundary WLs of the PB, the second set of read level offsets being associated with an MOL condition.

### Example 12

The system of any one of Examples 10-11, the operations comprising: determining that the PEC associated with the memory device corresponds to an end of life (EOL) period; and in response to determining that the PEC associated with the memory device corresponds to the EOL period, selecting a third set of read level offsets for reading data from the inner and boundary WLs of the PB, the third set of read level offsets being associated with an EOL condition.

### Example 13

The system of any one of Examples 1-12, wherein the condition comprises a slow charge loss (SCL) condition, the operations comprising: measuring SCL associated with the portion of the memory device; and in response to determining that the SCL associated with the portion of the memory device fails to transgress a threshold value, selecting a first set of read level offsets for reading data from inner and boundary WLs of the PB, the first set of read level offsets being associated with a first SCL condition.

### Example 14

The system of any one of Examples 1-13, wherein the condition comprises a temperature condition, the operations comprising: measuring temperature associated with the memory device; and selecting a first set of read level offsets for reading data from inner and boundary WLs of the PB based on the measured temperature.

### Example 15

The system of any one of Examples 1-14, wherein the memory device comprises a three-dimensional (3D) NAND device.

### Example 16

At least one non-transitory machine-readable storage medium comprising instructions that, when executed by a processing device, cause the processing device to perform operations comprising: generating a request to read a portion of a memory device; in response to determining that the portion corresponds to a partially programmed block (PB), determining a condition associated with an individual WL corresponding to the portion of the memory device; obtaining a read level offset from an individual WL offset table based on the condition associated with the individual WL; and reading data from the individual WL using the read level offset obtained from the individual WL offset table.

### Example 17

A method comprising: generating a request to read a portion of a memory device; in response to determining that the portion corresponds to a partially programmed block (PB), determining a condition associated with an individual WL corresponding to the portion of the memory device; obtaining a read level offset from an individual WL offset table based on the condition associated with the individual WL; and reading data from the individual WL using the read level offset obtained from the individual WL offset table.

### Example 18

The method of Example 17, wherein the portion comprises a plurality of WLs, the plurality of WLs comprising one or more inner WLs including the individual WL and a boundary WL, wherein the individual WL offset table comprises an inner WL offset table, comprising obtaining an additional read level offset from a boundary WL offset table based on the condition.

### Example 19

The method of Example 18, comprising: storing the inner WL offset table comprising a first plurality of read level offsets, each associated with a different condition of a plurality of conditions; and storing the boundary WL offset table comprising a second plurality of read level offsets, each associated with the different condition of the plurality of conditions, the boundary WL offset table representing a set of read level offsets for reading data from one or more WLs of the PB comprising a last programmed set of data.

### Example 20

The method of any one of Examples 18-19, comprising: storing the inner WL offset table comprising a first plurality of read level offsets, each associated with a different condition of a plurality of conditions; and storing the boundary WL offset table comprising a second plurality of read level offsets each associated with the different condition of the plurality of conditions, the boundary WL offset table representing a set of read level offsets for reading data from one or more WLs of the PB comprising a last programmed set of data.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Read disturb” refers to a phenomenon where repeated read operations on a specific WL in a NAND flash memory block cause unintended changes in the threshold voltages of adjacent cells on unselected WLs within the same block. This effect can potentially lead to data corruption in neighboring cells if left unmanaged, necessitating periodic data refresh or block relocation (folding) operations to maintain data integrity in NAND-based storage devices.

“Slow charge loss (SCL)” refers to charge retention loss or data retention loss that occurs in flash memory cells over time. SCL refers to the gradual leakage of electrical charge from the floating gate of a NAND cell, which can lead to data corruption or loss if left unchecked. This SCL is a natural aging process in flash memory and becomes more pronounced as the memory cells undergo more program/erase cycles and as the manufacturing process shrinks to smaller geometries. The rate of charge loss can be affected by factors such as temperature, the quality of the insulating oxide layer, and the overall design of the memory cell.

“Partially programmed block (PB)” refers to memory blocks that are not fully programmed and remain open with one or more sub-blocks that are empty and ready to be programmed. This is in contrast to full blocks (FBs) which are memory blocks that are fully programmed and closed. PBs require special handling for read operations, including the application of different read level offsets for inner word lines (WLs) and boundary WLs to reduce read disturb errors and other extrinsic defect related errors when reading data from these blocks.

“Inner WL” refers to any WL in a PB that does not contain the last programmed page. Inner WLs may require specific read level offsets retrieved from an inner WL offset table to reduce read disturb errors and other extrinsic defect related errors when reading data.

“Boundary WL” refers to the WL in a PB that contains the last programmed page. Boundary WLs may require special handling during read operations where both the inner WL offset and a modified boundary WL offset are combined to generate the read level offset used to read data, in order to reduce RBER associated with reading the last programmed portion.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

What is claimed is:

1. A system comprising:
a memory device;
a processing device, operatively coupled to the memory device, configured to perform operations comprising:
generating a request to read a portion of the memory device;
in response to determining that the portion corresponds to a partially programmed block (PB), determining a condition associated with an individual word line (WL) corresponding to the portion of the memory device;
obtaining a read level offset from an individual WL offset table based on the condition associated with the individual WL; and
reading data from the individual WL using the read level offset obtained from the individual WL offset table.

2. The system of claim 1, wherein the portion comprises a plurality of WLs, the plurality of WLs comprising one or more inner WLs including the individual WL and a boundary WL, wherein the individual WL offset table comprises an inner WL offset table, the operations comprising obtaining an additional read level offset from a boundary WL offset table based on the condition.

3. The system of claim 2, the operations comprising:
storing the inner WL offset table comprising a first plurality of read level offsets each associated with a different condition of a plurality of conditions; and
storing the boundary WL offset table comprising a second plurality of read level offsets each associated with the different condition of the plurality of conditions, the boundary WL offset table representing a set of read level offsets for reading data from one or more WLs of the PB comprising a last programmed set of data.

4. The system of claim 3, the operations comprising:
reading a first set of data from the one or more inner WLs of the portion using a first read level offset retrieved from the inner WL offset table; and
reading a second set of data from the boundary WL of the portion using a combined read level offset generated based on the first read level offset and a second read level offset retrieved from the boundary WL offset table.

5. The system of claim 4, the operations comprising:
adding the first read level offset and the second read level offset to generate the combined read level offset.

6. The system of claim 4, the operations comprising:
retrieving a read threshold voltage for reading data from the portion;
modifying the read threshold voltage by the first read level offset to read the first set of data; and
modifying the read threshold voltage by the combined read level offset to read the second set of data.

7. The system of claim 3, wherein the inner WL offset table associates a first WL group (WLG) with a first set of read level offsets corresponding to different levels of tri-level cell (TLC) storage, wherein the inner WL offset table associates a second WLG with a second set of read level offsets corresponding to the different levels of the TLC storage, wherein the boundary WL offset table associates the first WLG with a third set of read level offsets corresponding to the different levels of the TLC storage, and wherein the boundary WL offset table associates the second WLG with a fourth set of read level offsets corresponding to the different levels of the TLC storage.

8. The system of claim 1, the operations comprising:
maintaining a buffer that identifies which region of the memory device has been programmed last;
determining that the portion comprises the region of the memory device that has been programmed last; and
determining that the portion corresponds to the PB in response to determining that the portion comprises the region of the memory device that has been programmed last.

9. The system of claim 1, wherein the condition comprises a program erase count (PEC).

10. The system of claim 9, the operations comprising:
determining that the PEC associated with the memory device corresponds to a beginning of life (BOL) period; and
in response to determining that the PEC corresponds to the BOL period, selecting a first set of read level offsets for reading data from inner and boundary WLs of the PB, the first set of read level offsets being associated with a BOL condition.

11. The system of claim 10, the operations comprising:
determining that the PEC associated with the memory device corresponds to a middle of life (MOL) period; and
in response to determining that the PEC associated with the memory device corresponds to the MOL period, selecting a second set of read level offsets for reading data from the inner and boundary WLs of the PB, the second set of read level offsets being associated with a MOL condition.

12. The system of claim 10, the operations comprising:
determining that the PEC associated with the memory device corresponds to an end of life (EOL) period; and
in response to determining that the PEC associated with the memory device corresponds to the EOL period, selecting a third set of read level offsets for reading data from the inner and boundary WLs of the PB, the third set of read level offsets being associated with an EOL condition.

13. The system of claim 1, wherein the condition comprises a slow charge loss (SCL) condition, the operations comprising:
measuring SCL associated with the portion of the memory device; and
in response to determining that the SCL associated with the portion of the memory device fails to transgress a threshold value, selecting a first set of read level offsets for reading data from inner and boundary WLs of the PB, the first set of read level offsets being associated with a first SCL condition.

14. The system of claim 1, wherein the condition comprises a temperature condition, the operations comprising:
measuring temperature associated with the memory device; and
selecting a first set of read level offsets for reading data from inner and boundary WLs of the PB based on the measured temperature.

15. The system of claim 1, wherein the memory device comprises a three-dimensional (3D) NAND device.

16. At least one non-transitory machine-readable storage medium comprising instructions that, when executed by a processing device, cause the processing device to perform operations comprising:
generating a request to read a portion of a memory device;
in response to determining that the portion corresponds to a partially programmed block (PB), determining a condition associated with an individual word line (WL) corresponding to the portion of the memory device;
obtaining a read level offset from an individual WL offset table based on the condition associated with the individual WL; and
reading data from the individual WL using the read level offset obtained from the individual WL offset table.

17. A method comprising:
generating a request to read a portion of a memory device;
in response to determining that the portion corresponds to a partially programmed block (PB), determining a condition associated with an individual word line (WL) corresponding to the portion of the memory device;
obtaining a read level offset from an individual WL offset table based on the condition associated with the individual WL; and
reading data from the individual WL using the read level offset obtained from the individual WL offset table.

18. The method of claim 17, wherein the portion comprises a plurality of WLs, the plurality of WLs comprising one or more inner WLs including the individual WL and a boundary WL, wherein the individual WL offset table comprises an inner WL offset table, comprising obtaining an additional read level offset from a boundary WL offset table based on the condition.

19. The method of claim 18, comprising:
storing the inner WL offset table comprising a first plurality of read level offsets each associated with a different condition of a plurality of conditions; and
storing the boundary WL offset table comprising a second plurality of read level offsets each associated with the different condition of the plurality of conditions, the boundary WL offset table representing a set of read level offsets for reading data from one or more WLs of the PB comprising a last programmed set of data.

20. The method of claim 18, comprising:
storing the inner WL offset table comprising a first plurality of read level offsets each associated with a different condition of a plurality of conditions; and
storing the boundary WL offset table comprising a second plurality of read level offsets each associated with the different condition of the plurality of conditions, the boundary WL offset table representing a set of read level offsets for reading data from one or more WLs of the PB comprising a last programmed set of data.
